(19) United States
(12) Patent Application Publication
(10) Pub. No.: US 2025/0066549 A1
(43) Pub. Date: Feb. 27, 2025

(54) FLUORORESIN

(71) Applicant: CHEMOURS-MITSUI FLUOROPRODUCTS CO., LTD, Tokyo (JP)

(72) Inventors: KKEIGO HIGASHIDA, SHIZUOKA (JP); MASAKI MUGISAWA, SHIZUOKA (JP); GEN EGASHIRA, SHIZUOKA (JP); KAZUYA ICHINOSE, SHIZUOKA (JP)

(73) Assignee: CHEMOURS-MITSUI FLUOROPRODUCTS CO., LTD, TOKYO (JP)

(21) Appl. No.: 18/704,957

(22) PCT Filed: Oct. 26, 2022
(86) PCT No.: PCT/US2022/047850

§ 371 Date: Apr. 26, 2024

(30) Foreign Application Priority Data
Oct. 27, 2021 (JP) 2021-175868

(51) Int. Cl. C08G 65/40; C08J 5/24

(52) U.S. Cl. CPC C08G 65/4025; C08J 5/24; C08G 2650/48; C08J 2351/08

(57) ABSTRACT

To provide a novel fluororesin which is useful as an electronic substrate material for high-speed transmission. A fluororesin having a structure represented by formula (I) (n is within the range of from 1 to 100; L is a C₅-C₁₂ cycloalkylidene group which may have substituents; R³ and R⁴ are each independently a group selected from the group consisting of hydrogen, fluorine, C₁-C₁₀ saturated or unsaturated hydrocarbon groups in which some or all hydrogen is optionally substituted with halogens, and C₆-C₁₀ aryl groups in which some or all hydrogen is optionally substituted with halogens; and X is a group having an olefinic carbon-carbon double bond or a carbon-carbon triple bond).

Formula (I);

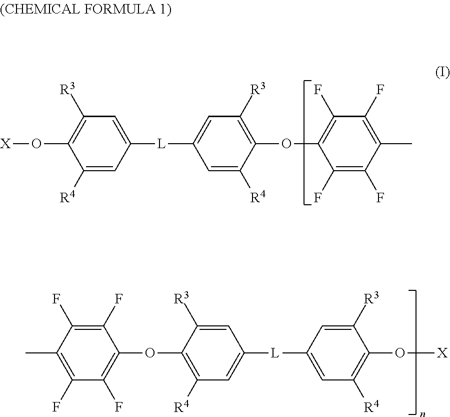

### CROSS REFERENCE TO RELATED APPLICATIONS

This application claims the benefit of priority of Japanese Patent Application No. 2021-175868 filed Oct. 27, 2021, the disclosure of which are incorporated herein by reference in their entirety.

### TECHNICAL FIELD

The present invention relates to a novel fluororesin. More particularly, the present invention relates to a novel fluororesin which is useful as an electronic substrate material for high-speed transmission.

### BACKGROUND ART

There has been an increasing demand for high-speed communication and high-speed transmission in recent years. To achieve high-speed transmission, it is necessary to transmit high-frequency signals without attenuation. Therefore, there is a demand for materials having a low dielectric constant and low dielectric loss as wire coating materials and substrate materials for signal transmission.

Conventionally, materials such as epoxy resins and polyphenylene ether resins have been used as resin materials for high-speed communication/transmission (see Patent Document 1). However, the electrical characteristics (dielectric constant, dielectric loss, and the like) of conventionally known epoxy resins and polyphenylene ether resins are inadequate for the demands of high-speed communication/transmission in recent years.

On the other hand, fluororesins are known as materials having excellent electrical characteristics. In particular, perfluororesins in which all hydrogen in the molecular chain is substituted with fluorine are known to exhibit particularly excellent electrical characteristics (dielectric constant, dielectric loss, and the like). However, fluororesins (perfluororesins) have problems in that they are easily deformed under stress and that they have a large thermal expansion coefficient, which makes them difficult to use as substrate materials. In order to resolve the problems described above, attempts have been made to mix fillers into fluororesins. However, it is known that mixing fillers affects electrical characteristics.

It has been proposed to use fluorinated poly(arylene ether) and crosslinking fluorinated poly(arylene ether) as dielectric materials in electronic parts (see Patent Documents 2 and 3). However, the electrical characteristics of these materials cannot satisfy the requirements of current high-speed communication/transmission.

In addition, there is a demand to reduce the crosslinking treatment temperature from the perspective of mass production and reduced production cost.

### PRIOR ART DOCUMENTS

### Patent Documents

PATENT DOCUMENT 1—Japanese Unexamined Patent Application Publication No. 2017-128718
PATENT DOCUMENT 2—U.S. Pat. No. 5,115,082 Specification
PATENT DOCUMENT 3—U.S. Pat. No. 5,179,188 Specification

### SUMMARY OF THE INVENTION

### Problem to be Solved by the Invention

As a substrate material for high-speed communication/transmission, there is a demand for a resin material having excellent electrical characteristics (low dielectric constant and low dielectric loss), excellent dimensional stability (low thermal expansion coefficient), high solvent solubility to facilitate thin film molding, and excellent crosslinking properties to enable film production by heating at around 200° C.

### Means for Solving the Problem

A first embodiment of the present invention relates to a fluororesin having a structure represented by formula (I):

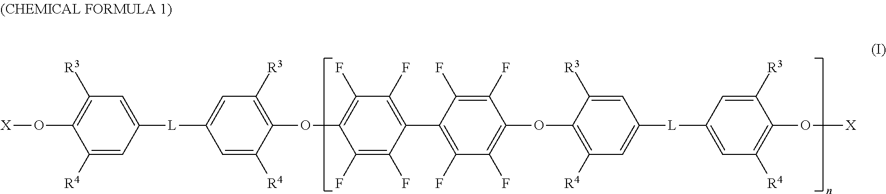

(wherein
n is within the range of from 1 to 100;
L is a C₅-C₁₂ cycloalkylidene group which may have substituents;
R³ and R⁴ are each independently a group selected from the group consisting of hydrogen, fluorine, C₁-C₁₀ saturated or unsaturated hydrocarbon groups in which some or all hydrogen is optionally substituted with halogens, and C₆-C₁₀ aryl groups in which some or all hydrogen is optionally substituted with halogens; and
X is a group having an olefinic carbon-carbon double bond or a carbon-carbon triple bond). Here, X may be a group that does not contain fluorine atoms. Preferably, L is selected from the group consisting of cyclopentylidene groups which may have substituents, cyclohexylidene groups which may have substituents, and cyclododecylidene groups which may have substituents.

A second embodiment of the present invention relates to a resin composition containing: the fluororesin of the first embodiment; and a crosslinking agent.

A third embodiment of the present invention relates to a prepreg containing: a semi-cured product of the fluororesin of the first embodiment; and a fibrous base material.

A fourth embodiment of the present invention relates to a prepreg containing: a semi-cured product of the resin composition according to the second embodiment; and a fibrous base material.

A fifth embodiment of the present invention relates to a copper-clad laminated sheet containing: a cured product of the prepreg according to the third or fourth embodiment; and at least one copper layer.

A sixth embodiment of the present invention relates to a printed circuit board containing: a cured product of the prepreg according to the third or fourth embodiment; and a conductor pattern formed on a surface of the cured product.

### Effect of the Invention

By adopting the configuration described above, the present invention can provide a fluororesin having excellent electrical characteristics (low dielectric constant and low dielectric loss), excellent dimensional stability, high solvent solubility, and excellent crosslinking properties. The fluororesin of the present invention can be suitably used as a material of a substrate for high-speed communication/transmission.

### EMBODIMENTS OF THE INVENTION

The fluororesin according to the first embodiment of the present invention has a structure represented by formula (I):

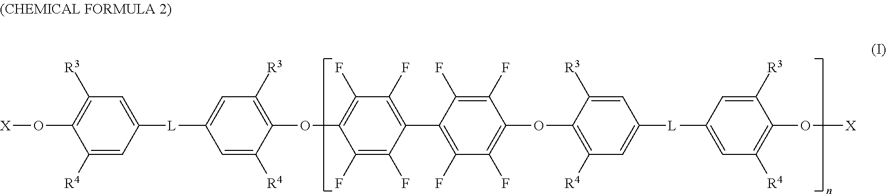

(wherein
n is within the range of from 1 to 100;
L is a C₅-C₁₂ cycloalkylidene group which may have substituents;
R³ and R⁴ are each independently a group selected from the group consisting of hydrogen, fluorine, C₁-C₁₀ saturated or unsaturated hydrocarbon groups in which some or all hydrogen is optionally substituted with halogens, and C₆-C₁₀ aryl groups in which some or all hydrogen is optionally substituted with halogens; and
X is a group having an olefinic carbon-carbon double bond or a carbon-carbon triple bond).

In formula (I), n is within the range of from 1 to 100, preferably within the range of from 3 to 50, and more preferably within the range of from 5 to 30. By setting n within the range described above, it is possible to simultaneously achieve sufficient thermal resistance, an appropriate glass transition temperature (Tg), and sufficient solvent solubility. In addition, by setting n within the range described above, it is possible to adjust the number of substituents X contained per unit weight of the resin so as to achieve suitable crosslinking properties and excellent electrical characteristics (dielectric constant, dielectric loss, and the like). Further, when forming a varnish using a fluororesin having the structure of formula (I), setting n within the range described above makes it possible to impart the varnish with suitable viscosity.

In formula (I), L is a C₅-C₁₂ cycloalkylidene which may have substituents. Preferably, is selected from the group consisting of cyclopentylidene groups which may have substituents, cyclohexylidene groups which may have substituents, and cyclododecylidene groups which may have substituents. Although not intended to be bound to a particular theory, cycloalkylidene groups may contribute to an increase in solvent solubility and a reduction in dielectric constant due to an increase in bulk.

Substituents present in the cycloalkylidene group may be C₁-C₁₀ saturated or unsaturated hydrocarbon groups in which some or all hydrogen is optionally substituted with halogens, or C₆-C₁₀ aryl groups in which some or all hydrogen is optionally substituted with halogens. Examples of C₁-C₁₀ saturated or unsaturated hydrocarbon groups in which some or all hydrogen is optionally substituted with halogens include methyl groups, ethyl groups, propyl groups, 2-methylpropyl groups (isobutyl groups), butyl groups, pentyl groups, trifluoromethyl groups, pentafluoroethyl groups, perfluoropropyl groups, vinyl groups, allyl groups, 1-methylvinyl groups, 2-butenyl groups, and 3-butenyl groups. Examples of C₆-C₁₀ aryl groups in which some or all hydrogen is optionally substituted with halogens include phenyl groups, naphthyl groups (including 1-isomers and 2-isomers), and perfluorophenyl groups.

In formula (I), R³ and R⁴ are each hydrogen, fluorine, a C₁-C₁₀ saturated or unsaturated hydrocarbon group in which some or all hydrogen is optionally substituted with halogens, or a C₆-C₁₀ aryl group in which some or all hydrogen is optionally substituted with halogens. Examples of C₁-C₁₀ saturated or unsaturated hydrocarbon groups in which some or all hydrogen is optionally substituted with halogens include methyl groups, ethyl groups, propyl groups, 2-methylpropyl groups (isobutyl groups), butyl groups, pentyl groups, trifluoromethyl groups, pentafluoroethyl groups, perfluoropropyl groups, vinyl groups, allyl groups, 1-methylvinyl groups, 2-butenyl groups, and 3-butenyl groups. Examples of C₆-C₁₀ aryl groups in which some or all hydrogen is optionally substituted with halogens include phenyl groups, naphthyl groups (including 1-isomers and 2-isomers), and perfluorophenyl groups.

In formula (I), X is a group having an olefinic carbon-carbon double bond or a carbon-carbon triple bond. In some modes, X is a group containing an olefinic carbon-carbon double bond or a carbon-carbon triple bond and at least one fluorine atom. In other modes, X is a group which contains an olefinic carbon-carbon double bond or a carbon-carbon triple bond but does not contain fluorine atoms. Examples of X include the structures of the following (X-1) to (X-10).

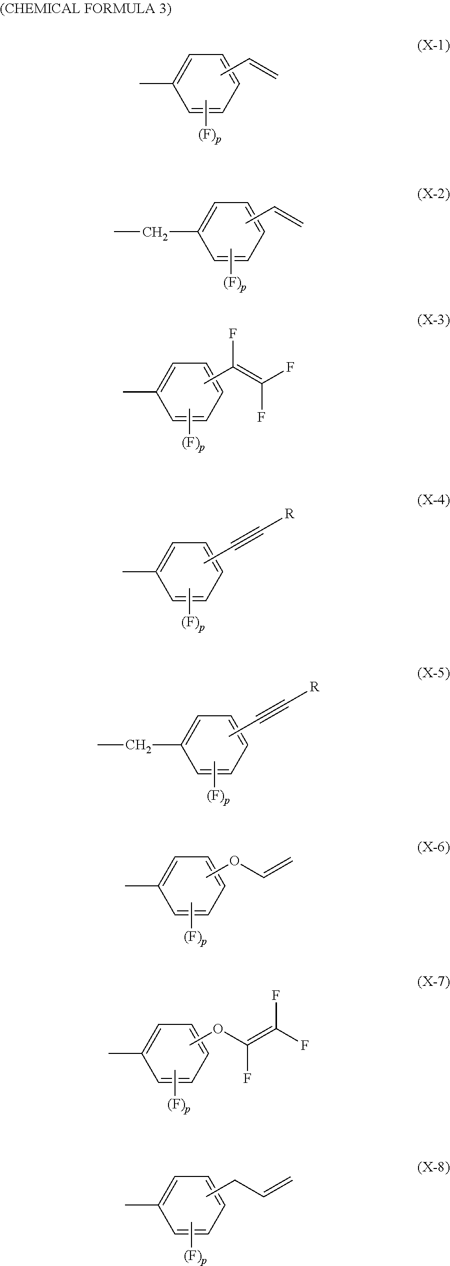

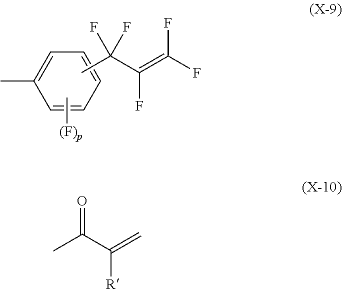

In the formulas, p is an integer from 0 to 4. In some modes, p is 4. In other modes, p is 0. R represents a group selected from the group consisting of C₁-C₁₀ alkyl groups and C₆-C₁₀ aryl groups. R′ represents a hydrogen atom or a C₁-C₁₀ alkyl group.

Preferably, X has the structures of the following (X-11) to (X-15).

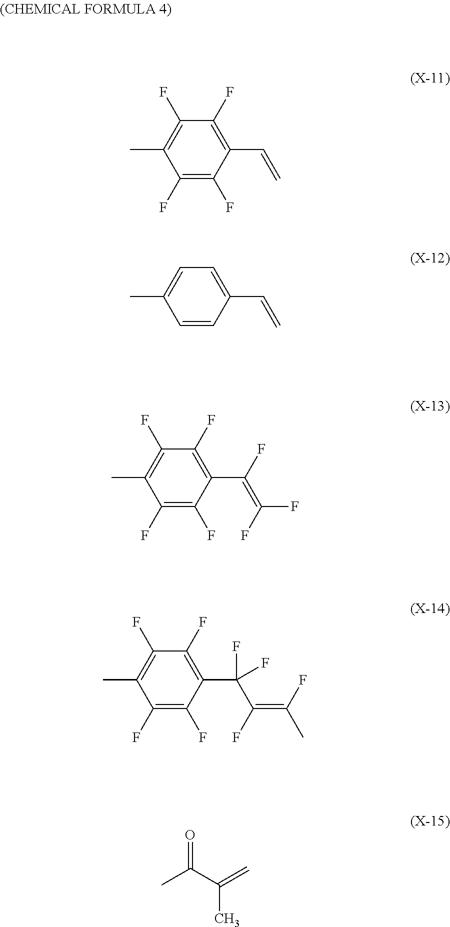

Preferable fluororesins in the present invention contain resins having the following structures, for example (in the formulas, “(*)” indicates a binding position).

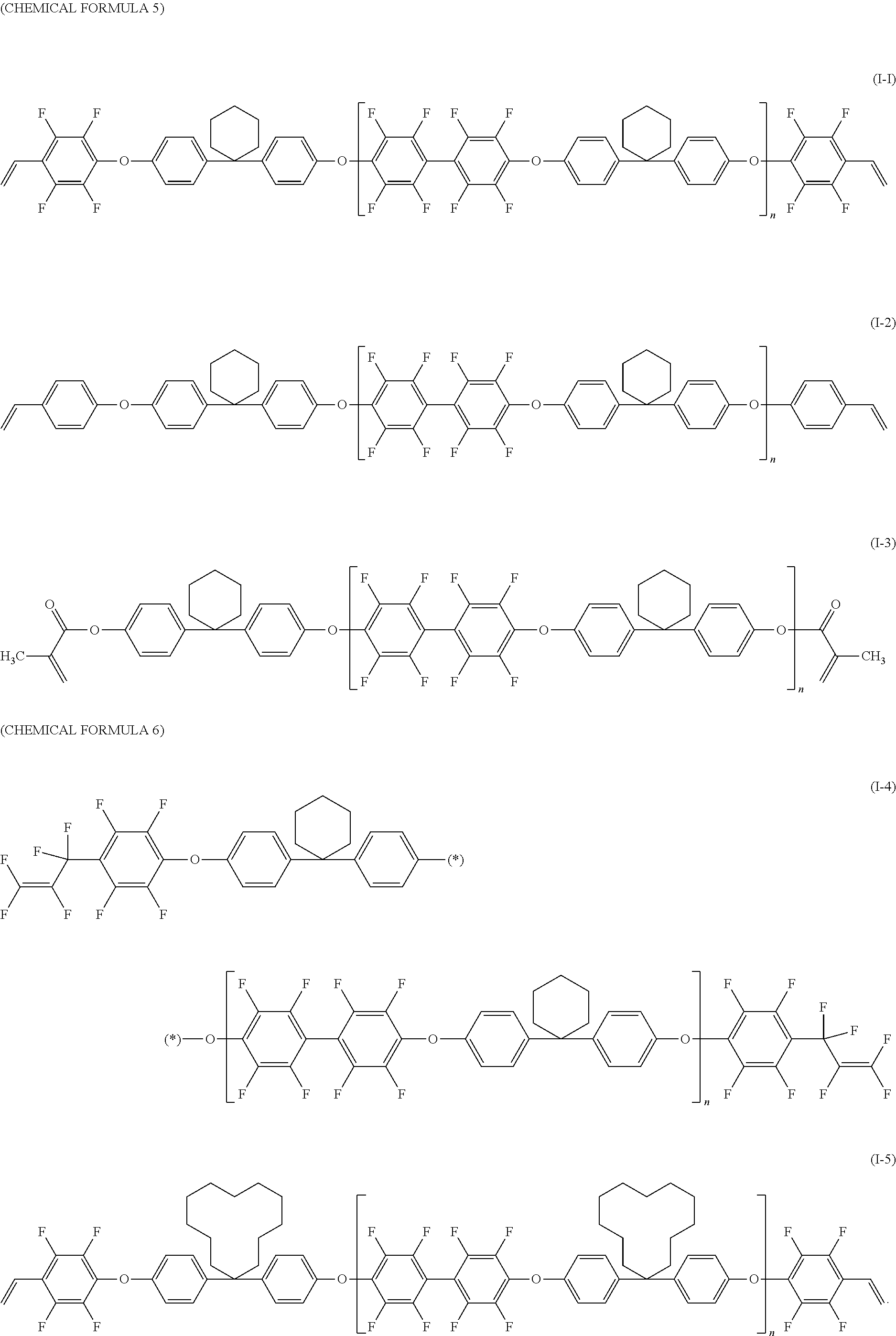

In the present invention, the fluororesin is preferably solvent-soluble. The fluororesin being “solvent-soluble” means that not less than 1 g and preferably not less than 10 g of the fluororesin is dissolved per 100 g of a solution obtained from a prescribed solvent. The fluororesin of this embodiment is preferably soluble in the hydrocarbons described below. In addition, the fluororesin of this embodiment is particularly preferably soluble in toluene from the perspective of cost.

The fluororesin of the present invention can be produced with a method including: (1) a step of condensing a bisphenol derivative (A) and a perfluorobiphenyl (B) in the presence of a base; and (2) a step of condensing a precursor (C) of a substituent X into the obtained condensate.

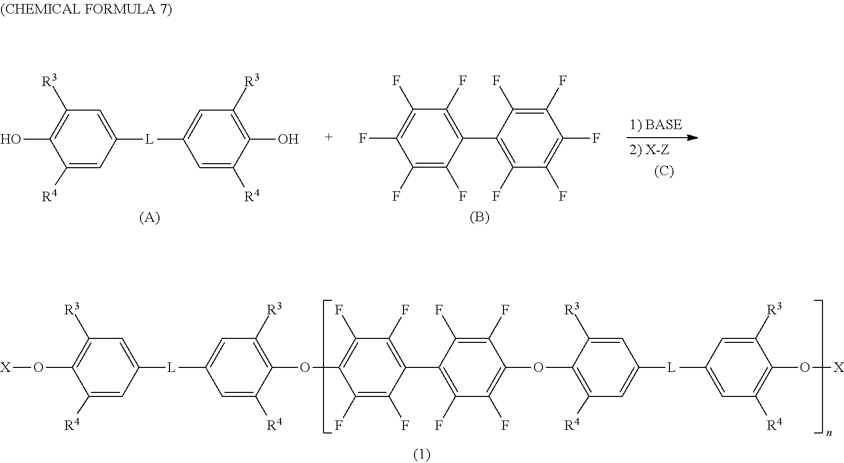

Z in the precursor (C) is a leaving group which is preferably selected from the group consisting of F, Cl, Br, and I and is more preferably F.

Preferable bases that may be used include carbonates, bicarbonates, and hydroxides of alkali metals. Examples of preferable bases include sodium carbonate, potassium carbonate, sodium bicarbonate, potassium bicarbonate, sodium hydroxide, and potassium hydroxide. It is preferable to use at least 1 mol and preferably from 2.0 to 2.6 mol of the base per 1 mol of the bisphenol derivative (A).

Step (1) and step (2) are preferably performed in an aprotic polar solvent or in a mixed solvent containing an aprotic polar solvent. Preferable aprotic polar solvents include N,N-dimethylformamide (DMF), N,N-dimethylacetamide (DMAc), dimethylsulfoxide (DMSO), sulfolane, and the like. The mixed solvent may contain a low-polarity solvent as long as it does not diminish the solubility of the fluororesin and does not affect the condensation reaction. Low-polarity solvents which may be used include toluene, xylene, benzene, tetrahydrofuran, benzotrifluoride((trifluoromethyl)benzene), xylenehexafluoride(1,3-bis(trifluoromethyl)benzene), and the like. Adding a low-polarity solvent makes it possible to vary the polarity (dielectric constant) of the solvent mixture and to control the speed of the condensation reaction.

Step (1) and step (2) are preferably performed continuously. The entire steps (1) and (2) are preferably performed under conditions with a reaction temperature of from 10 to 200° C. and a reaction time of from 1 to 80 hours, preferably a reaction temperature of from 20 to 180° C. and a reaction time of from 2 to 60 hours, and more preferably a reaction temperature of from 50 to 160° C. and a reaction time of from 3 to 40 hours.

The second embodiment of the present invention relates to a resin composition containing: the fluororesin of the first embodiment; and a crosslinking agent.

The crosslinking agent used in this embodiment includes a compound having two or more olefinic carbon-carbon double bonds in the molecule. Examples of the crosslinking agent used in this embodiment include polyfunctional methacrylate compounds having two or more methacrylic groups in the molecule, polyfunctional acrylate compounds having two or more acrylic groups in the molecule, trialkenyl isocyanurate compounds such as triallyl isocyanurate (TAIC), and divinylbenzene. Examples of polyfunctional acrylate/methacrylate compounds include dicyclopentadiene-type acrylate compounds such as tricyclodecane dimethanol diacrylate and dicyclopentadiene-type methacrylate compounds such as tricyclodecane dimethanol dimethacrylate.

The resin composition of this embodiment contains a crosslinking agent in an amount of 50 mass % and preferably 20 mass % on the basis of the total mass of the resin composition. In addition, in the resin composition of this embodiment, the mass ratio of the fluorine resin to the crosslinking agent is preferably within the range of from 9.5:0.5 to 0.5:5.5 and more preferably within the range of from 7.5:2.5 to 5.5:4.5. Using a mass ratio within this range makes it possible to impart the cured product of the resin composition with sufficient hardness.

The resin composition of this embodiment may further contain a solvent, a reaction initiator, and/or a filler. In addition, the resin composition of this embodiment may further contain any additives known in the art such as defoaming agents, thermal stabilizers, antistatic agents, UV absorbers, colorants (dyes or pigments), flame retardants, lubricants, and dispersants.

The resin composition of the present invention may be a varnish-like composition containing a solvent. In this embodiment, various solvents may be used. From the perspective of solvent solubility, an aprotic solvent is preferably used in the present invention. Solvents which may be used in this embodiment include hydrocarbons such as benzene, toluene, xylene, heptane, cyclohexane, methylcyclohexane, and mineral spirits; ketones such as acetone, methyl ethyl ketone (MEK), methyl isobutyl ketone (MIBK), and diisobutyl ketone (DIBK) and; cyclic ketones such as cyclohexanone, cycloheptanone, and cyclooctanone; esters such as ethyl acetate, butyl acetate, and γ-butyrolactone; cyclic ethers such as tetrahydrofuran (THF) and 1,3-dioxolane; amides such as N,N-dimethylformamide (DMF), diethylformamide (DEF), N,N-dimethylacetamide (DMAc), N-methylpyrrolidone (NMP), and N-cyclohexylpyrrolidone; sulfones such as sulfolane and dimethylsulfone; and sulfoxides such as dimethylsulfoxide (DMSO). Preferable solvents in the present invention are hydrocarbons, and particularly preferable are aromatic hydrocarbons.

The resin composition of this embodiment preferably contains a reaction initiator for crosslinking reactions. Although crosslinking/curing can be achieved by heating even in the absence of a reaction initiator, the presence of a reaction initiator enables more efficient crosslinking/curing under more relaxed conditions. Examples of reaction initiators which may be used include benzoyl peroxide, di-t-butylperoxide, t-butylhydroperoxide, dicumyl peroxide, cumyl hydroperoxide, α,α′-di(t-butylperoxy)-diisopropylbenzene (Perbutyl P available from the NOF Corporation), 2,5-dimethyl-2,5-di(t-butylperoxy)-3-hexyne, 3,3′,5,5′-tetramethyl-1,4-diphenoquinone, chloranil, 2,4,6-tri-t-butylphenoxyl, t-butylperoxyisopropyl monocarbonate, and azobis isobutyronitrile.

The resin composition of this embodiment may further contain one type or a plurality of types of fillers. The fillers may be organic fillers or inorganic fillers. Organic fillers which may be used include: engineering plastics such as polyphenylene sulfide, polyether ether ketone (PEEK), polyamides, polyimides, and polyamide imides; and solvent-insoluble fluororesins such as polytetrafluoroethylene (PTFE), perfluoroalkoxyalkane (PFA), and copolymers of tetrafluoroethylene and hexafluoropropylene (FEP). Inorganic fillers which may be used include: metals; metal oxides such as aluminum oxide, zinc oxide, tin oxide, and titanium oxide; metal hydroxides; metal titanates; zinc borate; zinc stannate; boehmite; silica; glass; silicon oxide; silicon carbide; boron nitride; calcium fluoride; carbon black; mica; talc; barium sulfate; and molybdenum disulfide. Solvent-insoluble fluororesns are preferable from the perspective of enhancing the electrical characteristics (dielectric constant, dielectric loss, and the like) of the cured product of the resin composition. In addition, silica is preferable in that the thermal expansion constant can be reduced without sacrificing the electrical characteristics (dielectric constant, dielectric loss, and the like) of the cured product of the resin composition.

The resin composition of this embodiment can be formed by mixing the fluororesin of the first embodiment, a crosslinking agent, and optionally selected components. Heating may be performed at the time of mixing. In addition, mixing can be performed using any mixing device known in the art such as various mixers, a ball mill, a bead mill, a planetary mixer, or a roll mill.

The third embodiment of the present invention relates to a prepreg containing: a semi-cured product of the fluororesin of the first embodiment; and a fibrous base material. The prepreg of this embodiment may further contain a reaction initiator for crosslinking reactions. The reaction initiators which may be used in this embodiment are the same as those of the second embodiment.

The fibrous base materials which may be used in the present invention include glass woven fabrics, aramid woven fabrics, polyester woven fabrics, carbon fiber woven fabrics, glass nonwoven fabrics, aramid nonwoven fabrics, polyester nonwoven fabrics, carbon fiber nonwoven fabrics, pulp paper, and linter paper. Preferable fibrous base materials are glass woven fabrics capable of realizing excellent mechanical strength. The fibrous base material preferably has a thickness of from 0.01 mm to 0.3 mm.

The prepreg of this embodiment can be formed by impregnating a fibrous base material with the fluororesin according to the first embodiment and an optionally selected reaction initiator and then drying it. Here, the impregnating fluororesin is preferably in a varnish state containing a solvent. The solvents which may be used are the same as those in the second embodiment. As a result of drying treatment, the solvent in the varnish is at least partially removed so that the fluororesin assumes a semi-cured state (so-called “B stage”). The impregnation step can be performed with any method known in the art such as immersion or coating. By performing the impregnation of the fluororesin and the optionally selected reaction initiator over the course of several cycles, the resin content in the prepreg can be adjusted. The conditions (temperature and time) of the drying step depend on the type of the fluororesin and the types of the optionally selected reaction initiator and/or solvent. For example, the drying step can be performed by heating to a temperature of from 80° C. to 170° C. over the course of 1 to 10 minutes.

The fourth embodiment of the present invention relates to a prepreg containing: a semi-cured product of the resin composition according to the second embodiment; and a fibrous base material. The fibrous base materials which can be used in this embodiment are the same as those of the third embodiment.

The prepreg of this embodiment can be formed by impregnating a fibrous base material with the resin composition of the second embodiment and drying it. Here, the impregnating resin composition is preferably in a varnish state containing a solvent. As a result of drying treatment, the solvent in the varnish is at least partially removed so that the fluororesin assumes a semi-cured state (so-called “B stage”). The impregnation step can be performed with any method known in the art such as immersion or coating. By performing the impregnation of the fluororesin over the course of several cycles, the resin content in the prepreg can be adjusted. The conditions (temperature and time) of the drying step depend on the type of the fluororesin and the types of the fluororesin, the crosslinking agent, and the optionally selected solvent contained in the resin composition. For example, the drying step can be performed by heating to a temperature of from 80° C. to 170° C. over the course of 1 to 10 minutes.

The fifth embodiment of the present invention relates to a copper-clad laminated sheet containing: a cured product of the prepreg according to the third or fourth embodiment; and at least one copper layer.

The copper-clad laminated sheet of this embodiment can be formed by laminating one or a plurality of prepregs, laminating a copper foil on one or both surfaces thereof, and integrating the obtained laminate by performing heat/pressure treatment. The resin composition in the copper-clad laminated sheet is preferably in a state in which curing is complete (so-called “C stage”). The conditions of heat/pressure treatment can be selected appropriately based on the thickness of the copper-clad laminated sheet to be produced, the composition of the resin composition in the prepreg, and the like. For example, a copper-clad laminated sheet can be produced by heating to a temperature of from 170° C. to 220° C. over the course of 60 to 150 minutes and then applying pressure of from 1.5 MPa (gauge pressure) to 5.0 MPa (gauge pressure).

The sixth embodiment of the present invention relates to a printed circuit board containing: a cured product of the prepreg according to the third or fourth embodiment; and a conductor pattern formed on a surface of the cured product.

The printed circuit board of this embodiment can be produced by etching the copper layer of the copper-clad laminated sheet of the fifth embodiment to form a conductor pattern. Alternatively, the printed circuit board can be produced by a method of laminating one or a plurality of prepregs and performing heat/pressure treatment to form a laminate and then laminating a conductive material on the surface of the laminate to form a conductor pattern.

### EXAMPLES

### Example 1—Synthesis of Fluororesin (1-1)

First, 0.805 g (3.0 mmol) of 1,1-bis(4-hydroxyphenyl)cyclohexane (bisphenol Z) and 0.912 g (6.6 mmol) of potassium carbonate were loaded into a glass reaction vessel. After the inside of the glass reaction vessel was decompressed to vacuum, it was subjected to nitrogen replacement. Next, 10 mL of DMAc was added to the glass reaction vessel. The reaction mixture was heated to 150° C. while stirring and was then stirred for three hours. After heating was complete, the reaction mixture was cooled to room temperature. Next, 0.802 g (2.4 mmol) of decafluorobiphenyl was added to the reaction mixture. The reaction mixture was heated to 70° C. while heating and was then stirred for four hours. Next, the reaction mixture was shielded from light, and 0.17 mL (0.233 g, 1.2 mmol) of 2,3,4,5,6-pentafluorostyrene was added. Stirring was continued for 15 hours at a temperature of 70° C. After stirring was complete, the reaction mixture was cooled to room temperature. The reaction mixture was then added to 0.5 L of purified water. The reaction mixture was suction-filtered, and the obtained solid was washed with purified water and methanol. After washing, the solid was dried under reduced pressure to obtain approximately 1.14 g of a fluororesin (1-1).

### Example 2—Synthesis of Fluororesin (1-2)

Approximately 1.09 g of a fluororesin (1-2) was obtained by repeating the procedure of Example 1 with the exception that 0.14 mL (0.143 g, 1.2 mmol) of 4-fluorostyrene was used instead of 2,3,4,5,6-pentafluorostyrene.

### Example 3—Synthesis of Fluororesin (1-3)

Approximately 1.07 g of a fluororesin (1-3) was obtained by repeating the procedure of Example 1 with the exception that 0.12 mL (0.125 g, 1.2 mmol) of methacryloyl chloride was used instead of 2,3,4,5,6-pentafluorostyrene.

### Example 4—Synthesis of Fluororesin (1-4)

Approximately 1.22 g of a fluororesin (1-4) was obtained by repeating the procedure of Example 1 with the exception that 0.21 mL (0.359 g, 1.2 mmol) of 3-(pentafluorophenyl)pentafluoro-1-propene was used instead of 2,3,4,5,6-pentafluorostyrene.

### Example 5—Synthesis of Fluororesin (1-5)

Approximately 1.52 g of a fluororesin (1-5) was obtained by repeating the procedure of Example 1 with the exception that 1.06 g (3.0 mmol) of 1,1-bis(4-hydroxyphenyl)cyclododecane was used instead of 1,1-bis(4-hydroxyphenyl)cyclohexane (bisphenol Z).

### Evaluation 1

Approximately 5 mg of the fluororesins obtained in Examples 1 to 5 was measured, and a thermogravimetric/differential thermal analyzer (DTA) was used to measure the thermogravimetric (TG) curve when heated from 23° C. to 500° C. at a heating rate of 10° C./min. The resulting TG curve was analyzed, and the temperature at which the weight decreased by 1% from prior to measurement was defined as the 1% decomposition temperature. The obtained results are shown in Table 1.

### Evaluation 2

A differential scanning calorimeter (manufactured by PerkinElmer Co., Ltd.) was used to analyze the fluororesins obtained in Examples 1 to 5. The temperature profile that was used is as follows.
(1) Heat from 30° C. to 350° C. at a heating rate of 50° C./min.
(2) Maintain temperature of 350° C. for one minute.
(3) Cool to 30° C. at a heating rate of 10° C./min.
(4) Maintain temperature of 30° C. for one minute.
(5) Heat to 350° C. at a heating rate of 10° C./min.

The Tm described in ASTM D3418-15 (midpoint temperature, temperature at the point where a line at an equal distance in the vertical axis direction from a line extending from each base line intersects with the curve at a section of stepwise change in the glass transition) was obtained from the melting curve obtained in step (5) and used as the glass transition temperature (Tg) of the fluororesin. The obtained results are shown in Table 1.

### Evaluation 3

Toluene was added to the fluororesins obtained in Examples 1 to 5, and the mixtures were heated to 80° C. to obtain 50 mass % toluene solutions of the fluororesins. Here, a fluororesin was assessed to be toluene-soluble if the fluororesin completely dissolved.

### Evaluation 4

An equal amount of cyclohexanone was added to the fluororesins obtained in Examples 1 to 5, and the mixtures were heated to 80° C. and stirred to obtain 50 mass % solutions of the fluororesins. The obtained cyclohexanone solutions were applied to aluminum sheets with a thickness of 0.1 mm. The obtained coatings were heated for 30 minutes at 110° C. and for one hour at 160° C. using a hot plate to remove the solvent (cyclohexanone). The resulting sheets to which the fluororesins were applied were heated for two hours at 220° C. using a hot plate to melt the fluororesins. After the sheets were then cooled to room temperature overnight, the coating films were peeled off and used as test pieces.

An RF impedance/material analyzer (E4991A manufactured by Agilent Technologies, Inc.) was used to measure the dielectric constant and dielectric loss of the test pieces at a frequency of 1 GHz. The obtained results are shown in Table 1.

TABLE 1

| | | | 1% Decom- | | Di- | Di- |
|---|---|---|---|---|---|---|
| | | | position | | electric | electric |
| | | Toluene- | temperature | Tg | constant | loss |
| Example | Resin | solubility | (° C.) | (° C.) | (1 GHz) | (1 GHz) |
| Example | (I-1) | ◯ | 344 | 135 | 2.65 | ≤0.001 |
| 1 | | | | | | |
| Example | (I-2) | ◯ | 345 | 172 | 2.28 | 0.012 |
| 2 | | | | | | |
| Example | (I-3) | ◯ | 314 | 137 | 2.75 | 0.010 |
| 3 | | | | | | |
| Example | (I-4) | ◯ | 237 | 122 | 2.43 | ≤0.001 |
| 4 | | | | | | |
| Example | (I-5) | ◯ | 248 | 182 | 2.88 | 0.0036 |
| 5 | | | | | | |

1. A fluororesin having a structure represented by formula (I): 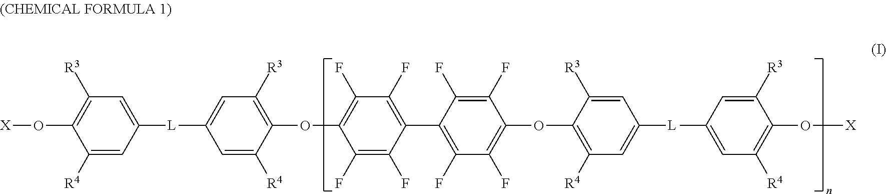
(wherein
n is within the range of from 1 to 100;
L is a C₅-C₁₂ cycloalkylidene group which may have substituents;
R³ and R⁴ are each independently a group selected from the group consisting of hydrogen, fluorine, C₁-C₁₀ saturated or unsaturated hydrocarbon groups in which some or all hydrogen is optionally substituted with halogens, and C₆-C₁₀ aryl groups in which some or all hydrogen is optionally substituted with halogens; and
X is a group having an olefinic carbon-carbon double bond or a carbon-carbon triple bond).

2. The fluororesin according to claim 1, wherein X does not contain fluorine atoms.

3. The fluororesin according to claim 1, wherein L is selected from the group consisting of cyclopentylidene groups which may have substituents, cyclohexylidene groups which may have substituents, and cyclododecylidene groups which may have substituents.

4. A resin composition comprising: the fluororesin according to claim 1; and a crosslinking agent.

5. A prepreg comprising: a semi-cured product of the fluororesin according to claim 1; and a fibrous base material.

6. A prepreg comprising: a semi-cured product of the resin composition according to claim 4; and a fibrous base material.

7. A copper-clad laminated sheet comprising: a cured product of the prepreg according to claim 5; and at least one copper layer.

8. A printed circuit board comprising: a cured product of the prepreg according to claim 5; and a conductor pattern formed on a surface thereof.

9. The fluororesin according to claim 2, wherein L is selected from the group consisting of cyclopentylidene groups which may have substituents, cyclohexylidene groups which may have substituents, and cyclododecylidene groups which may have substituents.

10. A resin composition comprising: the fluororesin according to claim 2; and a crosslinking agent.

11. A resin composition comprising: the fluororesin according to claim 3; and a crosslinking agent.

12. A prepreg comprising: a semi-cured product of the fluororesin according to claim 2; and a fibrous base material.

13. A prepreg comprising: a semi-cured product of the fluororesin according to claim 3; and a fibrous base material.

14. A copper-clad laminated sheet comprising: a cured product of the prepreg according to claim 6; and at least one copper layer.

15. A printed circuit board comprising: a cured product of the prepreg according to claim 6; and a conductor pattern formed on a surface thereof.
